(19) United States
(12) Patent Application Publication
(10) Pub. No.: US 2026/0282477 A1
(43) Pub. Date: Sep. 17, 2026

(54) SEMICONDUCTOR DEVICE AND METHOD FOR MANUFACTURING SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Masato IZUMI, Nonoichi Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/263,800

(22) Filed: Jul. 9, 2025

(30) Foreign Application Priority Data
Mar. 14, 2025 (JP) 2025-041518

(51) Int. Cl. H10D 62/53; H01L 21/22

(52) U.S. Cl. CPC H10D 62/53; H10P 32/171; H10P 32/18

(57) ABSTRACT

A semiconductor device includes a first electrode, a first semiconductor layer, a second semiconductor layer, a third semiconductor layer, a fourth semiconductor layer and a second electrode. The first semiconductor layer is connected to the first electrode. The second semiconductor layer contacts the first semiconductor layer. An impurity concentration of the second semiconductor layer is less than it of the first semiconductor layer. A defect density of the second semiconductor layer is greater than it of the first semiconductor layer. The third semiconductor layer contacts the second semiconductor layer. An impurity concentration of the third semiconductor layer is less than it of the second semiconductor layer. A defect density of the third semiconductor layer is less than it of the second semiconductor layer. The fourth semiconductor layer contacts the third semiconductor layer. The second electrode is connected to the fourth semiconductor layer.

### CROSS-REFERENCE TO RELATED APPLICATIONS

This application is based upon and claims the benefit of priority from Japanese Patent Application No.2025-041518, filed on Mar. 14, 2025; the entire contents of which are incorporated herein by reference.

### FIELD

Embodiments described herein relate generally to a semiconductor device and a method for manufacturing a semiconductor device.

### BACKGROUND

In a vertical diode using a silicon chip, an anode electrode and a cathode electrode are located at two surfaces of a silicon part; a p-type layer is located in a portion of the silicon part at the anode electrode side; an n-type layer is located in a portion of the silicon part at the cathode electrode side; and a low-concentration layer is located between the p-type layer and the n-type layer. The ohmic resistance between the n-type layer and the cathode electrode decreases as the impurity concentration of the n-type layer increases, which is advantageous because the conduction loss is reduced, but the switching loss is undesirably increased because the amount of carriers injected into the silicon part is increased.

### BRIEF DESCRIPTION OF THE DRAWINGS

FIG. 1 is a cross-sectional view showing a semiconductor device according to a first embodiment;

FIG. 2A is a graph showing an impurity concentration profile, in which the horizontal axis is the position along a line segment 50 shown in FIG. 1, and the vertical axis is the impurity concentration; and FIG. 2B is a graph showing a defect density profile, in which the horizontal axis is the position along the line segment 50 shown in FIG. 1, and the vertical axis is the defect density;

FIGS. 3 and 4 are process cross-sectional views showing a method for manufacturing the semiconductor device according to the first embodiment;

FIG. 5A is a graph showing an impurity concentration profile in the process shown in FIG. 4, in which the horizontal axis is the position, and the vertical axis is the impurity concentration; and FIG. 5B is a graph showing a defect density profile in the process shown in FIG. 4, in which the horizontal axis is the position, and the vertical axis is the defect density;

FIGS. 6 and 7 are process cross-sectional views showing the method for manufacturing the semiconductor device according to the first embodiment;

FIG. 8A is a graph showing an impurity concentration profile in the process shown in FIG. 7, in which the horizontal axis is the position, and the vertical axis is the impurity concentration; and FIG. 8B is a graph showing a defect density profile in the process shown in FIG. 7, in which the horizontal axis is the position, and the vertical axis is the defect density;

FIG. 9 is a cross-sectional view showing a semiconductor device according to a second embodiment;

FIG. 10 is a process cross-sectional view showing a method for manufacturing the semiconductor device according to the second embodiment; and

FIGS. 11 to 14 are process cross-sectional views showing a method for manufacturing a semiconductor device according to a third embodiment.

### DETAILED DESCRIPTION

In general, according to one embodiment, a semiconductor device includes a first electrode, a first semiconductor layer, a second semiconductor layer, a third semiconductor layer, a fourth semiconductor layer and a second electrode. The first semiconductor layer is connected to the first electrode. The first semiconductor layer is of a first conductivity type. The second semiconductor layer contacts the first semiconductor layer. The second semiconductor layer is of the first conductivity type. An impurity concentration of the second semiconductor layer is less than an impurity concentration of the first semiconductor layer. A defect density of the second semiconductor layer is greater than a defect density of the first semiconductor layer. The third semiconductor layer contacts the second semiconductor layer. The third semiconductor layer is of the first conductivity type. An impurity concentration of the third semiconductor layer is less than the impurity concentration of the second semiconductor layer. A defect density of the third semiconductor layer is less than a defect density of the second semiconductor layer. The fourth semiconductor layer contacts the third semiconductor layer. The fourth semiconductor layer is of a second conductivity type. The second electrode is connected to the fourth semiconductor layer.

In general, according to one embodiment, a method for manufacturing a semiconductor device includes implanting a first impurity into a first surface of a second semiconductor layer of an intermediate structure body to cause the second semiconductor layer to be of a first conductivity type. The intermediate structure body includes the second semiconductor layer of the first conductivity type, a third semiconductor layer contacting the second semiconductor layer, the third semiconductor layer being of the first conductivity type, an impurity concentration of the third semiconductor layer being less than an impurity concentration of the second semiconductor layer, a fourth semiconductor layer contacting the third semiconductor layer, the fourth semiconductor layer being of a second conductivity type, and a second electrode connected to the fourth semiconductor layer, the first surface being at a side of the second semiconductor layer opposite to the third semiconductor layer. The method includes activating the first impurity in the second semiconductor layer by heating the intermediate structure body from the first surface side so that the first impurity in the second semiconductor layer is activated in a thinner part of the second semiconductor layer than a part of the second semiconductor layer into which the first impurity was implanted. The method includes forming a first electrode connected to the first surface.

In general, according to one embodiment, a method for manufacturing a semiconductor device includes implanting a first impurity into a first region of a first surface of a second semiconductor layer of an intermediate structure body to cause the second semiconductor layer to be of a first conductivity type. The intermediate structure body includes the second semiconductor layer of the first conductivity type, a third semiconductor layer contacting the second semiconductor layer, the third semiconductor layer being of the first conductivity type, an impurity concentration of the third semiconductor layer being less than an impurity concentration of the second semiconductor layer, a fourth semiconductor layer contacting the third semiconductor layer, the fourth semiconductor layer being of a second conductivity type, and a second electrode connected to the fourth semiconductor layer, the first surface being at a side of the second semiconductor layer opposite to the third semiconductor layer. The method includes implanting a second impurity into a second region of the first surface to cause the second semiconductor layer to be of the second conductivity type. The method includes activating the first and second impurities. The method includes introducing, by implanting ions into the first region of the first surface, defects to a deeper part of the second semiconductor layer than a part of the second semiconductor layer into which the first impurity was implanted. The method includes forming a first electrode connected to the first surface.

### First Embodiment

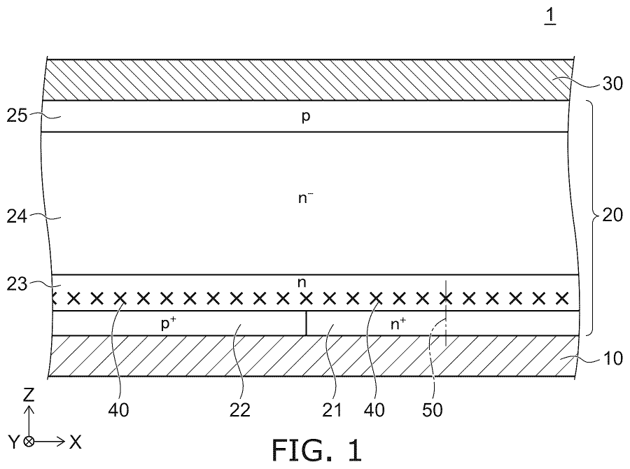

FIG. 1 is a cross-sectional view showing a semiconductor device according to an embodiment.

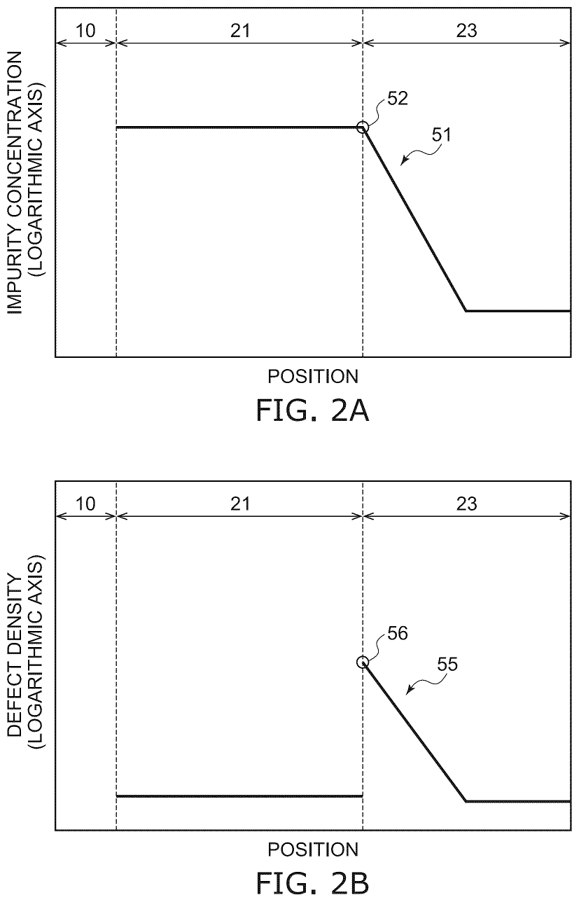

FIG. 2A is a graph showing an impurity concentration profile, in which the horizontal axis is the position along a line segment 50 shown in FIG. 1, and the vertical axis is the impurity concentration; and FIG. 2B is a graph showing a defect density profile, in which the horizontal axis is the position along the line segment 50 shown in FIG. 1, and the vertical axis is the defect density.

As shown in FIG. 1, the semiconductor device 1 according to the embodiment is a diode such as, for example, a FRD (Fast Recovery Diode), or a diode part of an IGBT (Insulated Gate Bipolar Transistor), an RC-IGBT (Reverse Conducting-IGBT), etc.

The semiconductor device 1 includes a cathode electrode 10 (a first electrode), a silicon part 20, and an anode electrode 30 (a second electrode). The silicon part 20 is located between the cathode electrode 10 and the anode electrode 30 and contacts the cathode electrode 10 and the anode electrode 30.

The silicon part 20 is substantially made of single-crystal silicon (Si); and impurities that form donors or acceptors are introduced to each portion to make the conductivity type the n-type or p-type. The silicon part 20 includes an n⁺-cathode layer 21 (a first semiconductor layer), a p⁺-cathode layer 22 (a fifth semiconductor layer), an n-buffer layer 23 (a second semiconductor layer), an n⁻-low-concentration layer 24 (a third semiconductor layer), and a p-anode layer 25 (a fourth semiconductor layer).

In the specification, an XYZ orthogonal coordinate system is employed for convenience of description. The direction from the cathode electrode 10 toward the anode electrode 30 is referred to as a “Z-direction”; and two mutually-orthogonal directions orthogonal to the Z-direction are referred to as an “X-direction” and a “Y-direction”. The Z-direction also is referred to as “up” or “above”, and the opposite direction also is referred to as “down” or “below”, but these expressions are for convenience and are independent of the direction of gravity.

The cathode electrode 10 is made of a conductive material and is, for example, a stacked film in which a gold (Au) layer, a nickel (Ni) layer, a titanium (Ti) layer, and an aluminum silicide (AlSi) layer are stacked in this order. The aluminum silicide layer contacts the silicon part 20. The composition and layer structure of the cathode electrode 10 are not limited thereto.

The n⁺-cathode layer 21 forms a portion of the lower surface of the silicon part 20, is located on the cathode electrode 10, contacts the cathode electrode 10, and is connected to the cathode electrode 10. In the specification, “connected” means an electrical connection. The conductivity type of the n⁺-cathode layer 21 is the n-type.

The p⁺-cathode layer 22 forms another portion of the lower surface of the silicon part 20, is located on the cathode electrode 10, contacts the cathode electrode 10, and is connected to the cathode electrode 10. The conductivity type of the p⁺-cathode layer 22 is the p-type. The n⁺-cathode layer 21 and the p⁺-cathode layer 22 are arranged along the upper surface of the cathode electrode 10. The thickness of the p⁺-cathode layer 22 is substantially equal to the thickness of the n⁺-cathode layer 21.

The n-buffer layer 23 is located on the n⁺-cathode layer 21 and on the p⁺-cathode layer 22 and contacts the n⁺-cathode layer 21 and the p⁺-cathode layer 22. The conductivity type of the n-buffer layer 23 is the n-type. The impurity concentration of the n-buffer layer 23 is less than the impurity concentration of the n⁺-cathode layer 21. In the specification, the “impurity concentration” refers to the impurity concentration contributing to the conduction of the semiconductor, and refers to the net concentration excluding the cancelled portion when one part includes both an impurity that forms donors and an impurity that forms acceptors. Although impurities that are not activated do not contribute to the conduction of the semiconductor as-is, such impurities are included in the impurity concentration for convenience of description in the specification.

The n-buffer layer 23 includes defects 40. The defects 40 are, for example, crystal defects, lattice defects, etc., and act as defect levels for carriers of the silicon part 20. The number of the defects 40 per unit volume of the n-buffer layer 23 (hereinbelow, referred to as the “defect density”) is greater than the defect density of the n⁺-cathode layer 21. More of the defects 40 are included in the lower part of the n-buffer layer 23, i.e., at the vicinity of the n⁺-cathode layer 21 and the vicinity of the p⁺-cathode layer 22.

The n⁻-low-concentration layer 24 is located on the n-buffer layer 23 and contacts the n-buffer layer 23. The conductivity type of the n⁻-low-concentration layer 24 is the n-type. The impurity concentration of the n⁻-low-concentration layer 24 is less than the impurity concentration of the n-buffer layer 23. The defect density of the n⁻-low-concentration layer 24 is less than the defect density of the n-buffer layer 23.

The p-anode layer 25 is located on the n⁻-low-concentration layer 24 and contacts the n⁻-low-concentration layer 24. The conductivity type of the p-anode layer 25 is the p-type.

The anode electrode 30 is made of a conductive material and is formed, for example, by selecting any of aluminum (Al), titanium (Ti), copper (Cu), or the like, or an alloy of such elements. The anode electrode 30 is connected to the p-anode layer 25.

As shown in FIG. 1, an imaginary line segment 50 passes through the n⁺-cathode layer 21 and the n-buffer layer 23 from the interface between the cathode electrode 10 and the n+-cathode layer 21. The line segment 50 extends in the Z-direction.

As shown in FIG. 2A, an impurity concentration profile 51 along the line segment 50 is substantially flat inside the n+-cathode layer 21, and decreases away from the n⁺-cathode layer 21 inside the n-buffer layer 23. Therefore, in the impurity concentration profile 51, the change rate of the impurity concentration in the n⁺-cathode layer 21 is less than the change rate of the impurity concentration in the n-buffer layer 23. The impurity concentration profile 51 has an inflection point 52 inside the n-buffer layer 23 at the interface with the n⁺-cathode layer 21.

As shown in FIG. 2B, a defect density profile 55 along the line segment 50 is substantially zero inside the n⁺-cathode layer 21, has a maximum value inside the n-buffer layer 23 at the interface with the n⁺-cathode layer 21, and decreases away from the n⁺-cathode layer 21. Therefore, the defect density profile 55 has a discontinuity 56 inside the n-buffer layer 23 at the interface with the n⁺-cathode layer 21.

A method for manufacturing the semiconductor device 1 according to the embodiment will now be described.

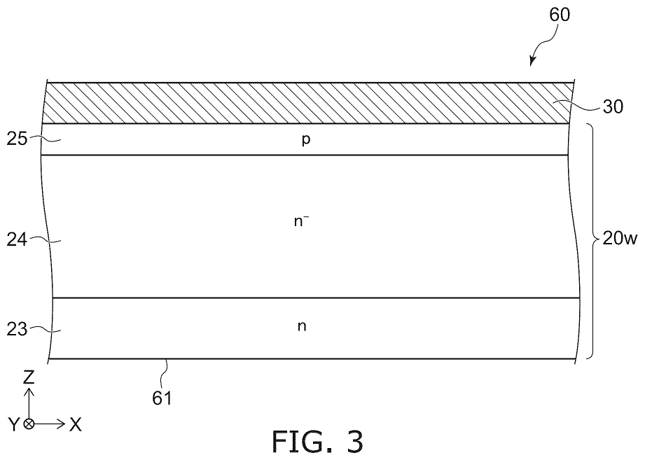

FIG. 3 is a process cross-sectional view showing the method for manufacturing the semiconductor device according to the embodiment.

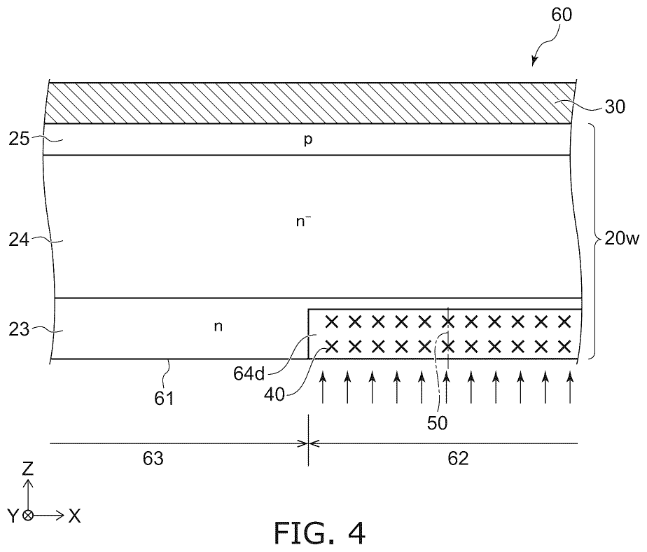

FIG. 4 is a process cross-sectional view showing the method for manufacturing the semiconductor device according to the embodiment.

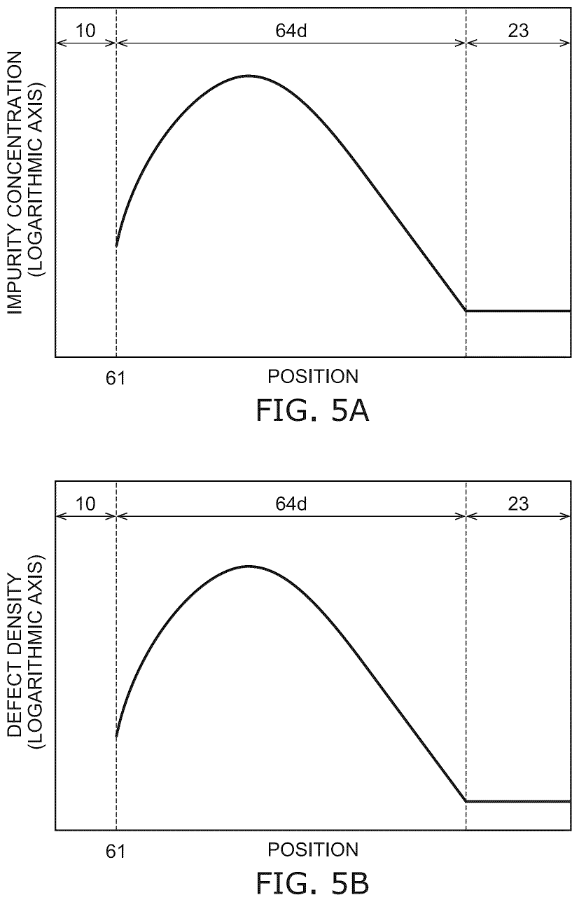

FIG. 5A is a graph showing an impurity concentration profile in the process shown in FIG. 4, in which the horizontal axis is the position, and the vertical axis is the impurity concentration; and FIG. 5B is a graph showing a defect density profile in the process shown in FIG. 4, in which the horizontal axis is the position, and the vertical axis is the defect density.

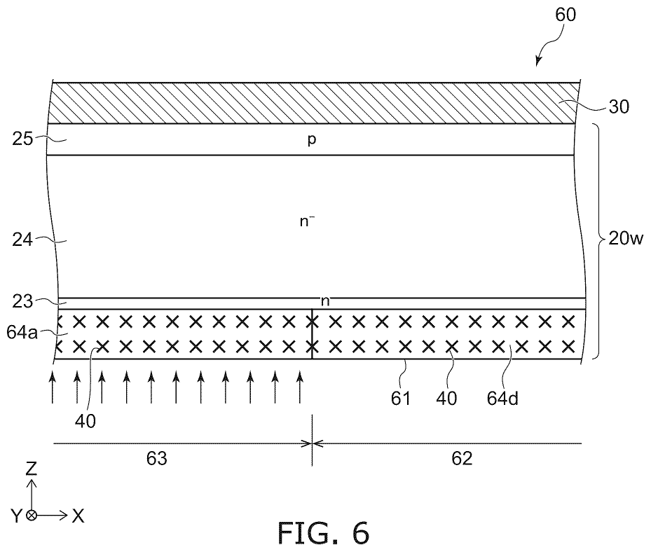

FIG. 6 is a process cross-sectional view showing the method for manufacturing the semiconductor device according to the embodiment.

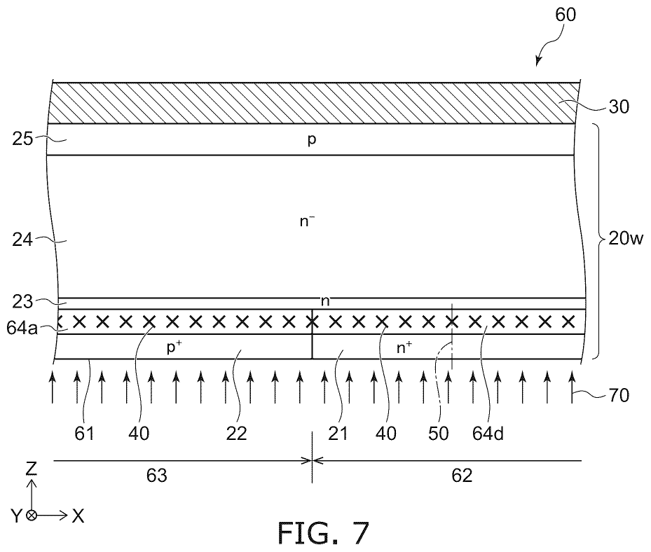

FIG. 7 is a process cross-sectional view showing the method for manufacturing the semiconductor device according to the embodiment.

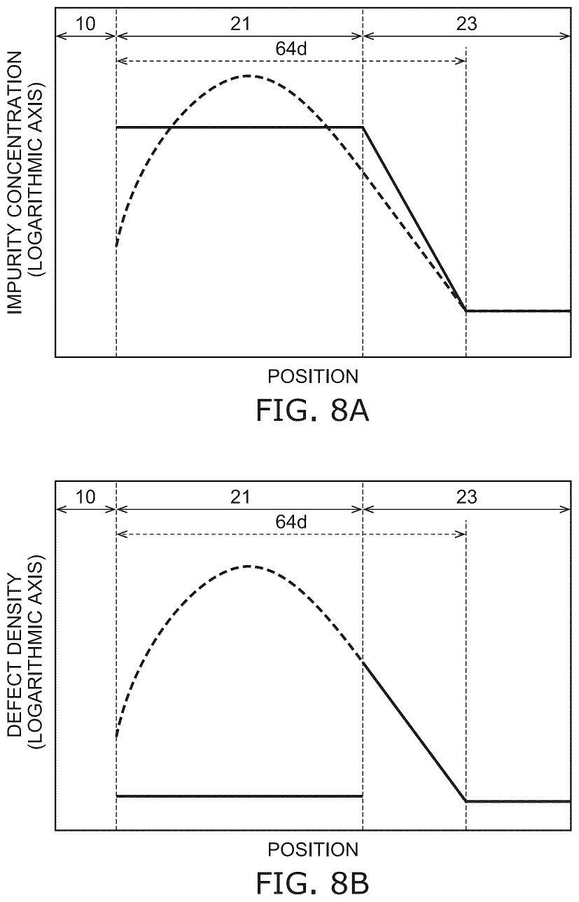

FIG. 8A is a graph showing an impurity concentration profile in the process shown in FIG. 7, in which the horizontal axis is the position, and the vertical axis is the impurity concentration; and FIG. 8B is a graph showing a defect density profile in the process shown in FIG. 7, in which the horizontal axis is the position, and the vertical axis is the defect density.

The positions of the horizontal axes of FIGS. 5A and 5B and FIGS. 8A and 8B are positions along the line segment 50 shown respectively in FIGS. 4 and 7.

First, a silicon wafer 20w is prepared as shown in FIG. 3. The lower part of the silicon wafer 20w is the n-buffer layer 23; and the upper part of the silicon wafer 20w is the n—low-concentration layer 24. Then, the p-anode layer 25 is formed in the upper part of the n⁻low-concentration layer 24 by ion-implanting an impurity that forms acceptors through the upper surface of the n⁻-low-concentration layer 24.

Then, the anode electrode 30 is formed on the upper surface of the silicon wafer 20w. Then, the silicon wafer 20w is thinned by polishing from the lower surface side. Thus, an intermediate structure body 60 that includes the anode electrode 30 and the silicon wafer 20w, which includes the n-buffer layer 23, the n⁻-low-concentration layer 24, and the p-anode layer 25, is made.

The silicon wafer 20w that is entirely the n⁻type may be prepared, the p-anode layer 25 and the anode electrode 30 may be formed at the upper surface side of the silicon wafer 20w, the silicon wafer 20w may be thinned by polishing from the lower surface side, an impurity that forms donors may be ion-implanted into the lower surface of the silicon wafer 20w, and laser annealing treatment may be performed on the lower surface of the silicon wafer 20w. Thus, the intermediate structure body 60 can be made.

Then, as shown in FIG. 4, an impurity that forms donors, i.e., an impurity that causes the conductivity type of the n-buffer layer 23 to be the n-type, is ion-implanted into a first region 62 of a lower surface 61 of the intermediate structure body 60, i.e., the surface (a first surface) of the n-buffer layer 23 at the side opposite to the n⁻-low-concentration layer 24. For example, phosphorus (P) is ion-implanted. As a result, a donor implantation layer 64d is formed in the first region 62 of the lower part of the n-buffer layer 23. The donor implantation layer 64d is a part into which an impurity that forms donors is implanted. At this time, the defects 40 also are introduced to the donor implantation layer 64d as the impurity is implanted.

At this time, as shown in FIG. 5A, the impurity concentration profile of the impurity implanted into the donor implantation layer 64d has a peak at a prescribed distance from the lower surface 61 of the intermediate structure body 60. As shown in FIG. 5B, the defect density profile of the defects 40 also has a profile corresponding to the impurity concentration profile shown in FIG. 5A, and has a peak at a prescribed distance from the lower surface 61 of the intermediate structure body 60.

Then, as shown in FIG. 6, an impurity that forms acceptors, i.e., an impurity that causes the conductivity type of the n-buffer layer 23 to be the p-type, is ion-implanted into a second region 63 of the lower surface 61 of the intermediate structure body 60. For example, boron (B), boron difluoride (BF₂), or arsenic (As) is ion-implanted. As a result, an acceptor implantation layer 64a is formed in the second region 63 of the lower part of the n-buffer layer 23. The acceptor implantation layer 64a is a part into which an impurity that forms acceptors is implanted. The impurity concentration profile and the defect density profile in the acceptor implantation layer 64a are similar to the profiles shown in FIGS. 5A and 5B.

Then, as shown in FIG. 7, a laser light 70 is irradiated on the first and second regions 62 and 63 of the lower surface 61 of the intermediate structure body 60. As a result, the intermediate structure body 60 is heated from the lower surface 61 side; and in the parts of the donor implantation layer 64d and the acceptor implantation layer 64a at the lower surface 61 side, the impurities are diffused and activated, and the defects 40 disappear. The part of the donor implantation layer 64d in which the impurities are diffused and activated and the defects 40 disappear becomes the n⁺-cathode layer 21. The part of the acceptor implantation layer 64a in which the impurities are diffused and activated and the defects 40 disappear becomes the p⁺-cathode layer 22.

At this time, the part of the donor implantation layer 64d that does not become the n⁺-cathode layer 21, i.e., the part of the donor implantation layer 64d where the impurities are substantially not diffused or activated, remains as a part of the n-buffer layer 23. The defects 40 also remain in this part. Similarly, the part of the acceptor implantation layer 64a that does not become the p⁺-cathode layer 22, i.e., the part of the acceptor implantation layer 64a where the impurities are substantially not diffused or activated, remains as a part of the n-buffer layer 23. The defects 40 also remain in this part.

As a result, as shown in FIG. 8A, the impurity concentration in the n⁺-cathode layer 21 becomes substantially uniform due to the diffusion; and the impurity concentration in the n-buffer layer 23 remains substantially the same as the impurity concentration shown in FIG. 5A. In FIG. 8A, the impurity concentration profile shown in FIG. 5A is illustrated by a broken line for reference. This is similar for the impurity concentration profile in the second region 63.

As shown in FIG. 8B, the defects 40 have substantially disappeared and the defect density is substantially zero in the n⁺-cathode layer 21; and the defect density in the n-buffer layer 23 remains substantially the same as the defect density shown in FIG. 5B. In FIG. 8B, the defect density profile shown in FIG. 5B is illustrated by a broken line for reference. The defect density profile in the second region 63 also is similar.

Then, as shown in FIG. 1, the cathode electrode 10 is formed on the lower surface 61 of the intermediate structure body 60. Then, the silicon wafer 20w is singulated by dicing. Thus, the semiconductor device 1 is manufactured.

Effects of the embodiment will now be described.

According to the embodiment, the n⁺-cathode layer 21 shown in FIG. 7 is thinner than the donor implantation layer 64d shown in FIG. 4. As a result, the impurities that are implanted into the part of the donor implantation layer 64d that did not become the n⁺-cathode layer 21 are not activated and do not contribute to the conduction of the silicon. Thus, a portion of the implanted impurities can be inactive, and so the impurities can be implanted with a high dose. As a result, the impurity concentration of the part of the n⁺-cathode layer 21 contacting the cathode electrode 10 is increased, and the ohmic resistance between the cathode electrode 10 and the n⁺-cathode layer 21 is reduced. As a result, the conduction loss of the semiconductor device 1 is reduced.

Also, because the activated impurity concentration can be suppressed, the amount of carriers injected from the n⁺-cathode layer 21 into the n-buffer layer 23 can be suppressed. As a result, the switching loss of the semiconductor device 1 is reduced.

According to the embodiment, the defects 40 can remain in the n-buffer layer 23 at the vicinity of the n⁺-cathode layer 21. As a result, the defects 40 can cause pair annihilation of electrons and holes; and the carrier lifetime can be controlled. The switching loss of the semiconductor device 1 can be reduced thereby.

According to the embodiment, by including the p⁺-cathode layer 22, carriers can be injected via the p⁺-cathode layer 22 when carriers become deficient at turn-off or at recovery due to carriers discharged from the silicon part 20. As a result, the depletion layer can be prevented from reaching the cathode electrode 10; and oscillations of the voltage between the cathode electrode 10 and the anode electrode 30 can be suppressed. As a result, the switching loss of the semiconductor device 1 can be more effectively reduced.

### Second Embodiment

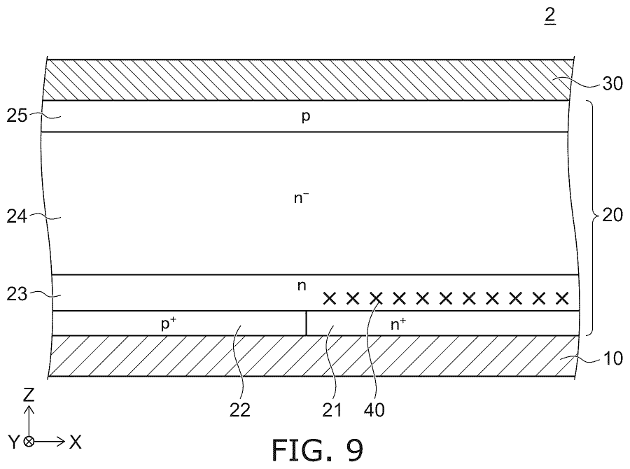

FIG. 9 is a cross-sectional view showing a semiconductor device according to an embodiment.

As shown in FIG. 9, the semiconductor device 2 according to the embodiment differs from the semiconductor device 1 according to the first embodiment in that the defects 40 are substantially not present in the second region 63, i.e., the region of the n-buffer layer 23 directly above the p⁺-cathode layer 22. The defects 40 are present in the first region 62, i.e., the region of the n-buffer layer 23 directly above the n⁺-cathode layer 21.

A method for manufacturing the semiconductor device according to the embodiment will now be described.

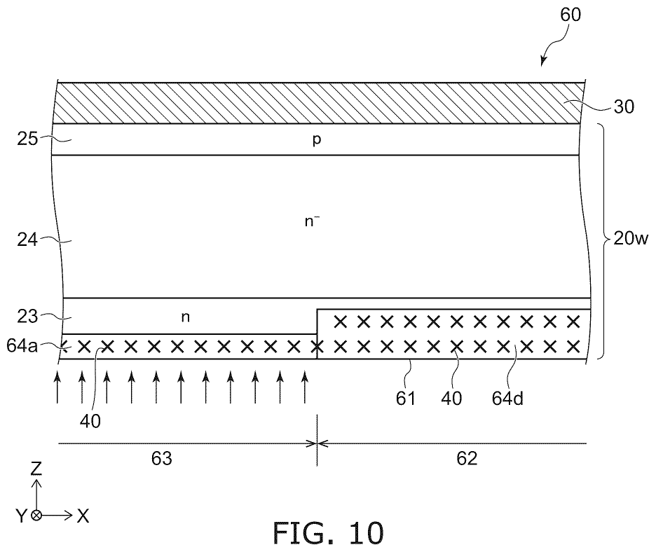

FIG. 10 is a process cross-sectional view showing the method for manufacturing the semiconductor device according to the embodiment.

First, the processes shown in FIGS. 3 and 4 are performed.

Then, as shown in FIG. 10, an impurity that forms acceptors is ion-implanted into the second region 63 of the lower surface 61 of the intermediate structure body 60. As a result, the acceptor implantation layer 64a is formed in the second region 63 of the lower part of the n-buffer layer 23. At this time, the acceleration voltage of the ion implantation is less than that of the first embodiment. As a result, the thickness of the acceptor implantation layer 64a is less than the thickness of the donor implantation layer 64d.

Then, the process shown in FIG. 7 is performed. In other words, the laser light 70 is irradiated on the first and second regions 62 and 63 of the lower surface 61 of the intermediate structure body 60. As a result, a part of the donor implantation layer 64d becomes the n⁺-cathode layer 21; and the remainder of the donor implantation layer 64d remains as the n-buffer layer 23 in which inactive impurities and the defects 40 remain. On the other hand, the acceptor implantation layer 64a is thinner than the donor implantation layer 64d, and so the entire acceptor implantation layer 64a is used to form the p⁺-cathode layer 22. As a result, inactive impurities and the defects 40 substantially do not remain in the region of the n-buffer layer 23 directly above the p⁺-cathode layer 22. Thus, the semiconductor device 2 according to the embodiment is manufactured.

According to the embodiment, the defects 40 are substantially not present in the region of the n-buffer layer 23 directly above the p⁺-cathode layer 22, and so carriers can be effectively injected from the cathode electrode 10 into the n-buffer layer 23 via the p⁺-cathode layer 22. Otherwise, the configuration, manufacturing method, and effects according to the embodiment are similar to those of the first embodiment.

### Third Embodiment

The configuration of a semiconductor device according to an embodiment is substantially the same as the configuration of the semiconductor device 2 shown in FIG. 9. However, in the region of the n-buffer layer 23 directly above the n⁺-cathode layer 21, the defects 40 are present, but inactive impurities are substantially not present.

A method for manufacturing the semiconductor device according to the embodiment will now be described.

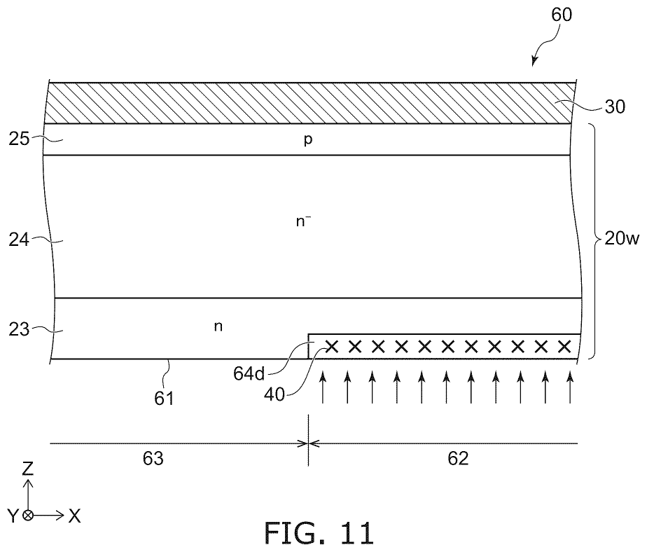

FIGS. 11 to 14 are process cross-sectional views showing the method for manufacturing the semiconductor device according to the embodiment.

First, the process shown in FIG. 3 is performed.

Then, as shown in FIG. 11, an impurity that forms donors is ion-implanted into the first region 62 of the lower surface 61 of the intermediate structure body 60. As a result, the donor implantation layer 64d is formed in the first region 62 of the lower part of the n-buffer layer 23. However, according to the embodiment, the acceleration voltage when ion-implanting the impurity is less than those of the first and second embodiments. Therefore, compared with the first and second embodiments, the donor implantation layer 64d is thin.

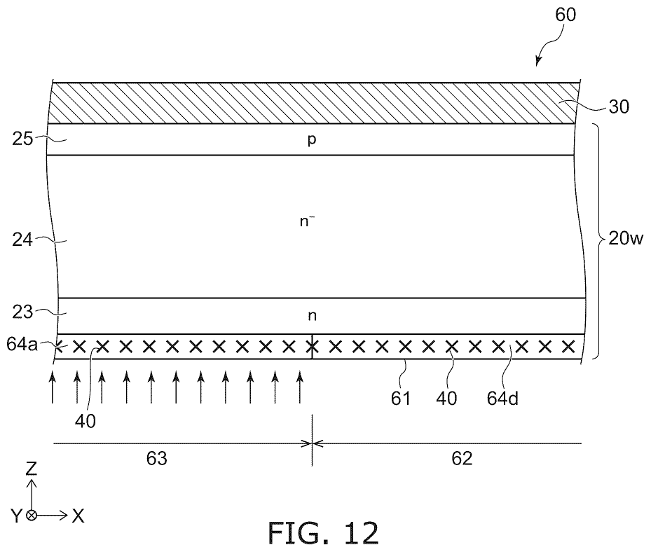

Continuing as shown in FIG. 12, an impurity that forms acceptors is ion-implanted into the second region 63 of the lower surface 61 of the intermediate structure body 60. As a result, the acceptor implantation layer 64a is formed in the second region 63 of the lower part of the n-buffer layer 23. At this time, the acceleration voltage of the ion implantation is about equal to that of the second embodiment. As a result, the thickness of the acceptor implantation layer 64a becomes thinner than the acceptor implantation layer 64a of the first embodiment, and becomes about equal to the thickness of the donor implantation layer 64d formed in FIG. 11.

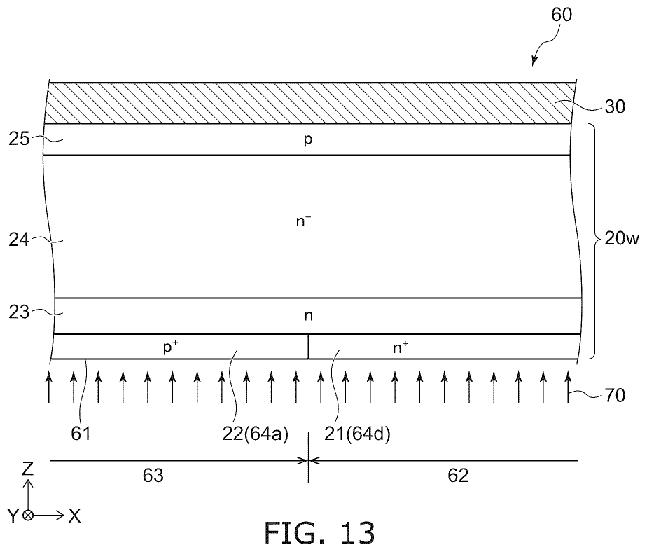

Then, as shown in FIG. 13, the laser light 70 is irradiated on the first and second regions 62 and 63 of the lower surface 61 of the intermediate structure body 60. As a result, the entire donor implantation layer 64d becomes the n⁺-cathode layer 21; and the entire acceptor implantation layer 64a becomes the p⁺-cathode layer 22. In other words, inactive impurities and the defects 40 substantially do not remain.

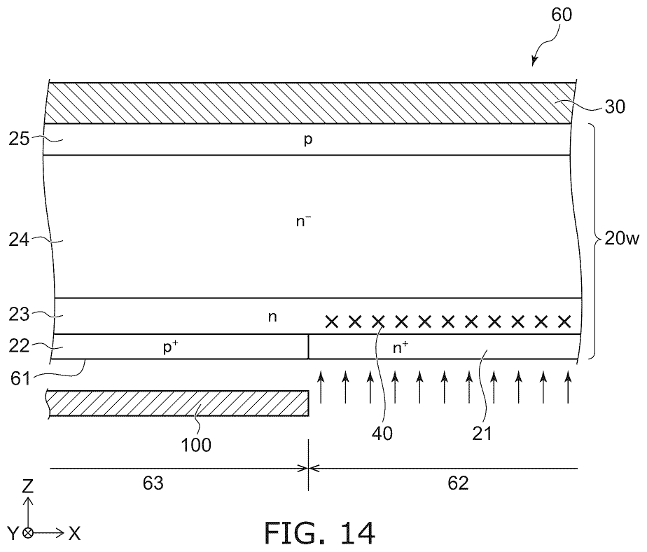

Continuing as shown in FIG. 14, protons, helium ions, or electrons are ion-implanted into the first region 62 while the second region 63 is masked with a mask 100. The acceleration voltage of the ion implantation is set to a voltage such that the ions pass through the n⁺-cathode layer 21 and reach the n-buffer layer 23. The mask 100 is, for example, a metal mask. As a result, the defects 40 are introduced to the region of the n-buffer layer 23 directly above the n⁺-cathode layer 21. Thus, the semiconductor device according to the embodiment is manufactured. Otherwise, the configuration, manufacturing method, and effects according to the embodiment are similar to those of the second embodiment.

Although only a diode part of the semiconductor device is described in the embodiments above, the semiconductor devices according to the embodiments may have a switching function such as that of an IGBT, an RC-IGBT, etc.

According to the embodiments above, a semiconductor device and a method for manufacturing a semiconductor device can be realized in which both a reduction of the conduction loss and a reduction of the switching loss can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Embodiments include the following aspects.

### Note 1

A semiconductor device, comprising:
a first electrode;
a first semiconductor layer connected to the first electrode, the first semiconductor layer being of a first conductivity type;
a second semiconductor layer contacting the first semiconductor layer, the second semiconductor layer being of the first conductivity type, an impurity concentration of the second semiconductor layer being less than an impurity concentration of the first semiconductor layer, a defect density of the second semiconductor layer being greater than a defect density of the first semiconductor layer;
a third semiconductor layer contacting the second semiconductor layer, the third semiconductor layer being of the first conductivity type, an impurity concentration of the third semiconductor layer being less than the impurity concentration of the second semiconductor layer, a defect density of the third semiconductor layer being less than a defect density of the second semiconductor layer;
a fourth semiconductor layer contacting the third semiconductor layer, the fourth semiconductor layer being of a second conductivity type; and
a second electrode connected to the fourth semiconductor layer.

### Note 2

The device according to note 1, wherein
the first semiconductor layer contacts the first electrode, and
in an impurity concentration profile along a line segment passing through the first and second semiconductor layers from an interface between the first electrode and the first semiconductor layer:
   a change rate of the impurity concentration in the first semiconductor layer is less than a change rate of the impurity concentration in the second semiconductor layer;
   the impurity concentration in the second semiconductor layer decreases away from the first semiconductor layer; and
   the impurity concentration profile has an inflection point at an interface between the first semiconductor layer and the second semiconductor layer.

### Note 3

The device according to note 1 or 2, wherein
the first semiconductor layer contacts the first electrode, and
in a defect density profile along a line segment passing through the first and second semiconductor layers from an interface between the first electrode and the first semiconductor layer:
   the defect density inside the second semiconductor layer decreases away from the first semiconductor layer; and
   the defect density profile has a discontinuity at an interface between the first semiconductor layer and the second semiconductor layer.

### Note 4

The device according to any one of notes 1 to 3, further comprising:
a fifth semiconductor layer connected to the first electrode,
the fifth semiconductor layer contacting the second semiconductor layer and being of the second conductivity type,
the first semiconductor layer and the fifth semiconductor layer being arranged along a direction parallel to an upper surface of the first electrode.

Note 5

A method for manufacturing a semiconductor device, the method comprising:
implanting a first impurity into a first surface of a second semiconductor layer of an intermediate structure body to cause the second semiconductor layer to be of a first conductivity type, the intermediate structure body including
   the second semiconductor layer of the first conductivity type,
   a third semiconductor layer contacting the second semiconductor layer, the third semiconductor layer being of the first conductivity type, an impurity concentration of the third semiconductor layer being less than an impurity concentration of the second semiconductor layer,
   a fourth semiconductor layer contacting the third semiconductor layer, the fourth semiconductor layer being of a second conductivity type, and
   a second electrode connected to the fourth semiconductor layer, the first surface being at a side of the second semiconductor layer opposite to the third semiconductor layer;
activating the first impurity in the second semiconductor layer by heating the intermediate structure body from the first surface side so that the first impurity in the second semiconductor layer is activated in a thinner part of the second semiconductor layer than a part of the second semiconductor layer into which the first impurity was implanted; and
forming a first electrode connected to the first surface.

### Note 6

The method according to note 5, further comprising:
before the activating of the first impurity, implanting a second impurity into the first surface to cause the second semiconductor layer to be of the second conductivity type.

### Note 7

The method according to note 6, wherein
a depth of a part of the intermediate structure body into which the second impurity is implanted is set to be less than a depth of a part of the intermediate structure body into which the first impurity is implanted.

### Note 8

The method according to any one of notes 5 to 7, wherein
the activating of the first impurity includes irradiating a laser light on the first surface.

### Note 9

A method for manufacturing a semiconductor device, the method comprising:
implanting a first impurity into a first region of a first surface of a second semiconductor layer of an intermediate structure body to cause the second semiconductor layer to be of a first conductivity type, the intermediate structure body including
   the second semiconductor layer of the first conductivity type,
   a third semiconductor layer contacting the second semiconductor layer, the third semiconductor layer being of the first conductivity type, an impurity concentration of the third semiconductor layer being less than an impurity concentration of the second semiconductor layer,
   a fourth semiconductor layer contacting the third semiconductor layer, the fourth semiconductor layer being of a second conductivity type, and
   a second electrode connected to the fourth semiconductor layer, the first surface being at a side of the second semiconductor layer opposite to the third semiconductor layer;
implanting a second impurity into a second region of the first surface to cause the second semiconductor layer to be of the second conductivity type;
activating the first and second impurities;
introducing, by implanting ions into the first region of the first surface, defects to a deeper part of the second semiconductor layer than a part of the second semiconductor layer into which the first impurity was implanted; and
forming a first electrode connected to the first surface.

### Note 10

The method according to note 9, wherein
the introducing of the defects includes injecting protons, helium ions, or electrons while the second region is masked.

### Note 11

The method according to note 9 or 10, wherein
the activating of the first and second impurities includes irradiating a laser light on the first surface.

What is claimed is:

1. A semiconductor device, comprising:
a first electrode;
a first semiconductor layer connected to the first electrode, the first semiconductor layer being of a first conductivity type;
a second semiconductor layer contacting the first semiconductor layer, the second semiconductor layer being of the first conductivity type, an impurity concentration of the second semiconductor layer being less than an impurity concentration of the first semiconductor layer, a defect density of the second semiconductor layer being greater than a defect density of the first semiconductor layer;
a third semiconductor layer contacting the second semiconductor layer, the third semiconductor layer being of the first conductivity type, an impurity concentration of the third semiconductor layer being less than the impurity concentration of the second semiconductor layer, a defect density of the third semiconductor layer being less than a defect density of the second semiconductor layer;
a fourth semiconductor layer contacting the third semiconductor layer, the fourth semiconductor layer being of a second conductivity type; and
a second electrode connected to the fourth semiconductor layer.

2. The device according to claim 1, wherein
the first semiconductor layer contacts the first electrode, and
in an impurity concentration profile along a line segment passing through the first and second semiconductor layers from an interface between the first electrode and the first semiconductor layer:
a change rate of the impurity concentration in the first semiconductor layer is less than a change rate of the impurity concentration in the second semiconductor layer;
the impurity concentration in the second semiconductor layer decreases away from the first semiconductor layer; and
the impurity concentration profile has an inflection point at an interface between the first semiconductor layer and the second semiconductor layer.

3. The device according to claim 1, wherein
the first semiconductor layer contacts the first electrode, and
in a defect density profile along a line segment passing through the first and second semiconductor layers from an interface between the first electrode and the first semiconductor layer:
the defect density inside the second semiconductor layer decreases away from the first semiconductor layer; and
the defect density profile has a discontinuity at an interface between the first semiconductor layer and the second semiconductor layer.

4. The device according to claim 1, further comprising:
a fifth semiconductor layer connected to the first electrode,
the fifth semiconductor layer contacting the second semiconductor layer and being of the second conductivity type,
the first semiconductor layer and the fifth semiconductor layer being arranged along a direction parallel to an upper surface of the first electrode.

5. A method for manufacturing a semiconductor device, the method comprising:
implanting a first impurity into a first surface of a second semiconductor layer of an intermediate structure body to cause the second semiconductor layer to be of a first conductivity type, the intermediate structure body including
the second semiconductor layer of the first conductivity type,
a third semiconductor layer contacting the second semiconductor layer, the third semiconductor layer being of the first conductivity type, an impurity concentration of the third semiconductor layer being less than an impurity concentration of the second semiconductor layer,
a fourth semiconductor layer contacting the third semiconductor layer, the fourth semiconductor layer being of a second conductivity type, and
a second electrode connected to the fourth semiconductor layer, the first surface being at a side of the second semiconductor layer opposite to the third semiconductor layer;
activating the first impurity in the second semiconductor layer by heating the intermediate structure body from the first surface side so that the first impurity in the second semiconductor layer is activated in a thinner part of the second semiconductor layer than a part of the second semiconductor layer into which the first impurity was implanted; and
forming a first electrode connected to the first surface.

6. The method according to claim 5, further comprising:
before the activating of the first impurity, implanting a second impurity into the first surface to cause the second semiconductor layer to be of the second conductivity type.

7. The method according to claim 6, wherein
a depth of a part of the intermediate structure body into which the second impurity is implanted is set to be less than a depth of a part of the intermediate structure body into which the first impurity is implanted.

8. The method according to claim 5, wherein
the activating of the first impurity includes irradiating a laser light on the first surface.

9. A method for manufacturing a semiconductor device, the method comprising:
implanting a first impurity into a first region of a first surface of a second semiconductor layer of an intermediate structure body to cause the second semiconductor layer to be of a first conductivity type, the intermediate structure body including
the second semiconductor layer of the first conductivity type,
a third semiconductor layer contacting the second semiconductor layer, the third semiconductor layer being of the first conductivity type, an impurity concentration of the third semiconductor layer being less than an impurity concentration of the second semiconductor layer,
a fourth semiconductor layer contacting the third semiconductor layer, the fourth semiconductor layer being of a second conductivity type, and
a second electrode connected to the fourth semiconductor layer, the first surface being at a side of the second semiconductor layer opposite to the third semiconductor layer;
implanting a second impurity into a second region of the first surface to cause the second semiconductor layer to be of the second conductivity type;
activating the first and second impurities;
introducing, by implanting ions into the first region of the first surface, defects to a deeper part of the second semiconductor layer than a part of the second semiconductor layer into which the first impurity was implanted; and
forming a first electrode connected to the first surface.

10. The method according to claim 9, wherein
the introducing of the defects includes injecting protons, helium ions, or electrons while the second region is masked.

11. The method according to claim 9, wherein
the activating of the first and second impurities includes irradiating a laser light on the first surface.
